(19) United States
(12) Patent Application Publication
(10) Pub. No.: US 2011/0287625 A1
(43) Pub. Date: Nov. 24, 2011

(54) METHODS OF FORMING A PATTERN, METHODS OF FORMING A GATE STRUCTURE AND METHODS OF MANUFACTURING A SEMICONDUCTOR DEVICE USING THE SAME

(76) Inventors: Dae-Hyuk Kang, Hwaseong-si (KR); Kun-Tack Lee, Suwon-si (KR); Dae-Hong Eom, Hwaseong-si (KR); Bo-Un Yoon, Seoul (KR); Jeong-Nam Han, Seoul (KR)

(21) Appl. No.: 13/079,202

(22) Filed: Apr. 4, 2011

(30) Foreign Application Priority Data
May 24, 2010 (KR) 10-2010-0047930

(51) Int. Cl. H01L 21/336

(52) U.S. Cl. 438/594; 438/585; 257/E21.409; 257/E21.422

(57) ABSTRACT

A method of forming a pattern in a semiconductor device includes forming an etching object layer on a substrate, the etching object layer is an oxide that is substantially free of impurities. A mask is formed on the etching object layer, the mask is an oxide that includes impurities. The etching object layer is patterned using the mask as an etching mask and then the mask is removed. The mask is removed using an etchant having an etching selectivity to an oxide that is substantially free of impurities and an oxide that includes impurities during removing of the mask to limit damage to the patterned etching object layer during removal of the mask.

### CLAIM OF PRIORITY

This application claims priority under 35 USC §119 to Korean Patent Application No. 10-2010-0047930 filed on May 24, 2010 in the Korean Intellectual Property Office (KIPO), the contents of which are herein incorporated by reference in their entirety.

### BACKGROUND

Example embodiments according to the inventive concept relate to methods of forming a pattern, methods of forming a gate structure and methods of manufacturing a semiconductor device using the same. More particularly, example embodiments according to the inventive concept relate to methods of forming a pattern using a mask, methods of forming a gate structure using a mask, and methods of manufacturing a semiconductor device using the same.

When a gate structure is formed, after forming a gate insulation layer and a gate electrode layer, the gate electrode layer and the gate insulation layer may be patterned using a gate mask. If the gate mask is not removed, the gate structure may fail as a result of a high aspect ratio. However, during the removal of the gate mask, the gate insulation layer may be damaged.

### SUMMARY

Some embodiments according to the inventive concept include methods of forming a pattern in a semiconductor device that includes forming an etching object layer on a substrate, the etching object layer is an oxide that is substantially free of impurities. A mask is formed on the etching object layer, the mask is an oxide that includes impurities. The etching object layer is patterned using the mask as an etching mask and then the mask is removed. The mask is removed using an etchant having an etching selectivity to an oxide that is substantially free of impurities and an oxide that includes impurities during removing of the mask to limit damage to the patterned etching object layer during removal of the mask.

In other embodiments according to the inventive concept, the etching object layer comprises an oxide that does not include any impurities and the mask comprises an oxide that is doped with impurities. The mask may include boro phosphor silicate glass (BPSG) and the etching object layer may include silicon oxide. The etchant used in removing the mask may be a gas that includes hydrogen fluoride and deionized water vapor. The etchant used in removing the mask may be a solution including hydrogen fluoride, deionized water, and one of a polar solvent and a strong acid containing sulfuric acid. The etchant used in removing the mask may be a solution including about 80 to about 99.9% by weight of organic solvent, about 0.01 to about 10% by weight of hydrogen fluoride, and about 0.1 to about 10% by weight of deionized water.

In further embodiments according to the inventive concept, the etchant used in removing the mask is a gas that includes hydrogen fluoride. The gas may further include deionized water vapor.

In other embodiments according to the inventive concept, forming the mask is preceded by forming a barrier layer on the etching object layer of a material that limits movement of impurities from the mask into the etching object layer. Patterning the etching object layer further includes patterning the barrier layer. Forming the barrier layer may include forming the barrier layer using silicon nitride to a thickness of about 50Å.

In yet further embodiments according to the inventive concept, a method of forming a gate structure includes forming a gate insulation layer on a substrate, the gate insulation layer having an oxide that is substantially free of impurities. A gate electrode layer is formed on the gate insulation layer; A gate mask is formed on the gate electrode layer, the gate mask comprising an oxide that includes impurities. The gate electrode layer and the gate insulation layer are patterned using the gate mask as an etching mask and then the gate mask is removed using an etchant having an etching selectivity to an oxide that is substantially free of impurities and an oxide that includes impurities during removing of the gate mask to limit damage to the patterned gate electrode layer during removal of the gate mask.

In other embodiments according to the inventive concept, the gate mask includes boro phosphor silicate glass (BPSG) and the gate mask is an oxide that is doped with impurities. The etchant used in removing the gate mask may be a gas including hydrogen fluoride. The etchant used in removing the gate mask may be a solution including hydrogen fluoride, deionized water, and one of a polar solvent and a strong acid containing sulfuric acid. Forming the gate mask may be preceded by forming a barrier layer on the gate electrode layer of a material that limits movement of impurities from the gate mask into the gate electrode layer and patterning the gate electrode layer may further include patterning the barrier layer.

In yet other embodiments according to the inventive concept, a method of forming a semiconductor device includes forming an insulation layer on a substrate, the insulation layer being an oxide that is substantially free of impurities. A conductive layer is formed on the insulation layer. A first hard mask is formed on the conductive layer, the first hard mask including an oxide doped with impurities. The conductive layer and the insulation layer are patterned using the first hard mask as an etching mask to form a floating gate layer and a tunnel insulation layer, respectively. The first hard mask layer is removed using an etchant having an etching selectivity to an oxide that is substantially free of impurities and an oxide that includes impurities during removing of the first hard mask to limit damage to the patterned conductive layer during removal of the first hard mask. A dielectric layer is then formed on the substrate, the dielectric layer covering the floating gate layer. A control gate layer is formed on the dielectric layer. A second hard mask layer is formed on the control gate layer, the second hard mask layer including an oxide doped with impurities. The control gate layer, the dielectric layer, the floating gate layer and the tunnel insulation layer are patterned using the second hard mask as an etching mask to form a control gate, a dielectric layer pattern, a floating gate and a tunnel insulation layer pattern, respectively. The second hard mask is removed.

In further embodiments according to the inventive concept, the etchant used in removing the first hard mask and an etchant used in removing the second hard masks is a gas including hydrogen fluoride. Removing the first and second hard masks may be performed using a solution including hydrogen fluoride, deionized water, and one of a polar solvent and a strong acid containing sulfuric acid. Patterning the conductive layer and the insulation layer may further include forming a trench by removing an upper portion of the substrate and the control gate and the dielectric layer pattern may be patterned to extend in a given direction, and the floating gate and the tunnel insulation layer pattern may be patterned to have an island shape.

### BRIEF DESCRIPTION OF THE DRAWINGS

Example embodiments according to the inventive concept will be more clearly understood from the following detailed description taken in conjunction with the accompanying drawings. FIGS. 1 to 12 represent non-limiting, example embodiments according to the inventive concept as described herein.

FIGS. 1 to 3 are cross-sectional views illustrating a method of forming a pattern in accordance with some embodiments according to the inventive concept;

FIGS. 4 to 6 are cross-sectional views illustrating a method of forming a gate structure in accordance with some embodiments according to the inventive concept;

FIGS. 7 to 12 are cross-sectional views illustrating a method of forming a semiconductor device in accordance with some embodiments according to the inventive concept; and

FIG. 13 is a block diagram illustrating a system including the pattern or the gate structure formed by the method illustrated with reference to FIGS. 1 to 12 in accordance with some embodiments according to the inventive concept.

### DETAILED DESCRIPTION OF THE EMBODIMENTS ACCORDING TO THE INVENTIVE CONCEPT

Various example embodiments according to the inventive concept will be described more fully hereinafter with reference to the accompanying drawings, in which some example embodiments according to the inventive concept are shown. The present inventive concept may, however, be embodied in many different forms and should not be construed as limited to the example embodiments according to the inventive concept set forth herein. Rather, these example embodiments according to the inventive concept are provided so that this description will be thorough and complete, and will fully convey the scope of the present inventive concept to those skilled in the art and the present invention will only be defined by the appended claims. In the drawings, the sizes and relative sizes of layers and regions may be exaggerated for clarity. Like reference numerals refer to like elements throughout the specification.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments according to the inventive concept only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments according to the inventive concept are described herein with reference to cross-sectional illustrations that are schematic illustrations of idealized example embodiments according to the inventive concept (and intermediate structures). As such, variations from the shapes of the illustrations as a result, for example, of manufacturing techniques and/or tolerances, are to be expected. Thus, example embodiments according to the inventive concept should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments according to the inventive concept will be explained in detail with reference to the accompanying drawings. FIGS. 1 to 3 are cross-sectional views illustrating a method of forming a pattern in accordance with example embodiments according to the inventive concept. Referring to FIG. 1, an etching object layer 110 and a mask layer 160 may be sequentially formed on a substrate 100. A barrier layer 150 may be further formed between the etching object layer 110 and the mask layer 160.

The substrate 100 may be a semiconductor substrate, e. g., a silicon substrate, a germanium substrate, a silicon-germanium substrate, etc., a silicon-on-insulator (SOI) substrate, a germanium-on-insulator (GOI) substrate, or a single crystalline metal oxide substrate.

In some embodiments according to the inventive concept, the etching object layer 110 may be formed from an oxide that is substantially free of impurities. For example, the etching object layer 110 may be formed by performing a heat oxidation process or a radical oxidation process on a top surface of the substrate 100. By way of further example, the etching object layer 110 may be formed by depositing an oxide material on the substrate 100.

The mask layer 160 may be formed from a material having an etching selectivity with respect to the etching object layer 110. For example, the mask layer 160 may be formed using an oxide doped with impurities. The mask layer 160 may be formed using boro phosphor silicate glass (BPSG) in some embodiments according to the inventive concept.

The barrier layer 150 may be formed using silicon nitride. The barrier layer 150 may limit or even prevent the impurities doped in the mask layer 160 from moving to the etching object layer 110. To facilitate subsequent removal thereof, the barrier layer 150 may be formed to have a relatively narrow thickness of, for example, about 50Å.

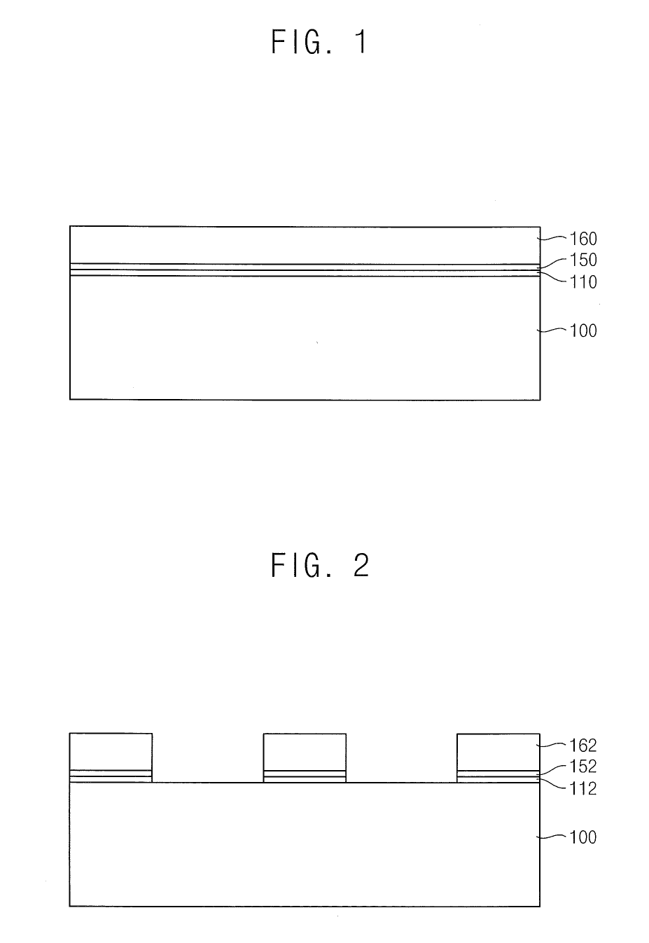

Referring now to FIG. 2, the mask layer 160 may be patterned by a photolithography process to form a mask 162. The etching object layer 110 may be patterned using the mask 162 as an etching mask to form a pattern 112. When the barrier layer 150 is formed between the etching object layer 110 and the mask layer 160, the barrier layer 150 may also be patterned to form a barrier layer pattern 152.

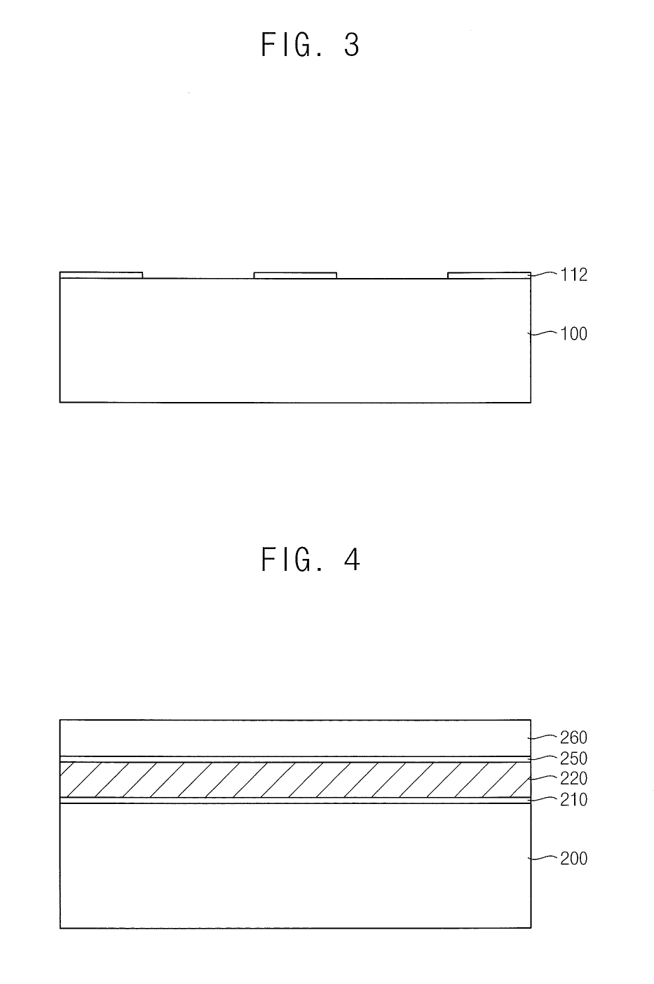

Referring to FIG. 3, the mask 162 may be removed after forming the pattern(s). In some embodiments according to the inventive concept, the mask 162 may be removed using a gas including hydrogen fluoride (HF). The gas may further include deionized water vapor. In some embodiments, the removal of the mask 162 using the gas may be performed at a room temperature or a temperature below about 100° C. The gas may have a high etching selectivity between an oxide doped with impurities and an oxide not including impurities, which may limit or even prevent damage to the pattern 112 during the removal of the mask 162.

In other embodiments according to the inventive concept, the mask 162 may be removed using a solution including hydrogen fluoride, deionized water, and one of a polar solvent and a strong acid containing sulfuric acid. The polar solvent may include, for example, alcohols, carboxylic acid, carbonyl, ether, ester, etc. In some embodiments according to the inventive concept, the solution may include about 80 to about 99.9% by weight of organic solvent, about 0.01 to about 10% by weight of hydrogen fluoride and about 0.1 to about 10% by weight of deionized water. In some embodiments according to the inventive concept, the removal of the mask 162 using the solution may be performed at a room temperature or a temperature below about 100° C. The solution may have a high etching selectivity between an oxide doped with impurities and an oxide not including impurities, which may limit or even prevent damage to the pattern 112 during the removal of the mask 162.

When the barrier layer pattern 152 has been formed, the barrier layer pattern 152 may be removed.

As illustrated above, when a pattern substantially free of impurities (or not including impurities) is formed, the mask 162 may be formed using a material having an etching selectivity with respect to the etching object layer 110, e. g., an oxide doped with impurities, and the etching object layer 110 may be patterned to form the pattern 112. Thus, the pattern 112 may not be damaged during the removal of the mask 162, which may provide improved performance characteristics in a semiconductor device including the pattern 112.

FIGS. 4 to 6 are cross-sectional views illustrating a method of forming a gate structure in accordance with some embodiments according to the inventive concept. Referring to FIG. 4, a gate insulation layer 210, a gate electrode layer 220 and a gate mask layer 260 may be sequentially formed on a substrate 200. A barrier layer 250 may also be formed between the gate electrode layer 220 and the gate mask layer 260.

The substrate 200 may be a semiconductor substrate, e. g., a silicon substrate, a germanium substrate, a silicon-germanium substrate, etc., a SOI substrate, a GOI substrate, or a single crystalline metal oxide substrate.

In some embodiments according to the inventive concept, the gate insulation layer 210 may be formed from an oxide that is substantially free of (or does not include) impurities. In some embodiments according to the inventive concept, the gate insulation layer 210 may be formed by performing a heat oxidation process or a radical oxidation process on a top surface of the substrate 200. In some embodiments according to the inventive concept, the gate insulation layer 210 may be formed by depositing an oxide on the substrate 200.

The gate electrode layer 220 may be formed using doped polysilicon, a metal, a metal silicide, a metal nitride or the like. The gate mask layer 260 may be formed using a material having an etching selectivity with respect to the gate insulation layer 210. In some embodiments according to the inventive concept, the gate mask layer 260 may be formed using an oxide doped with impurities. For example, the gate mask layer 260 may be formed using BPSG.

The barrier layer 250 may be formed using silicon nitride and may limit or even prevent the impurities doped in the gate mask layer 260 from moving to the gate electrode layer 220. To facilitate the removal thereof, the barrier layer 250 may be formed to have a relatively small thickness of, for example, about 50Å.

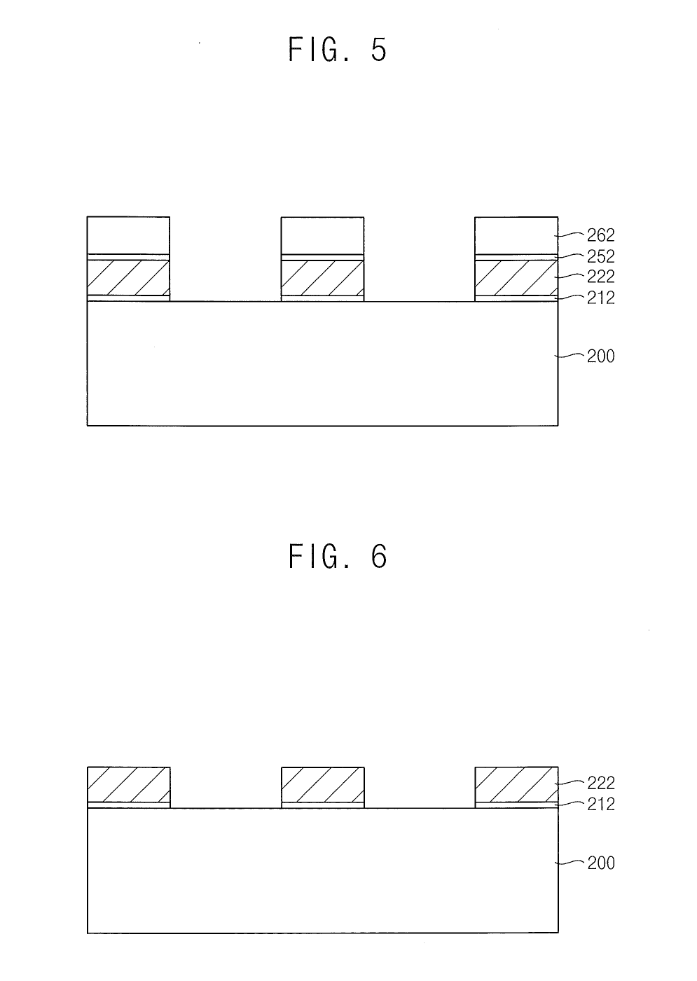

Referring to FIG. 5, the gate mask layer 260 may be patterned by a photolithography process to form a gate mask 262. The gate electrode layer 220 and the gate insulation layer 210 may be patterned using the gate mask 262 as an etching mask to form a gate electrode 222 and a gate insulation layer pattern 212, respectively. When the barrier layer 250 is formed between the gate electrode layer 220 and the gate mask layer 260, the barrier layer 250 may also be patterned to form a barrier layer pattern 252.

Referring to FIG. 6, the gate mask 262 may be removed to form the gate structure including the gate insulation layer pattern 212 and the gate electrode 222. In some embodiments according to the inventive concept, the gate mask 262 may be removed using a gas including hydrogen fluoride (HF). The gas may further include deionized water vapor. The gas may have a high etching selectivity between an oxide doped with impurities and an oxide not including impurities, so that damage to the gate insulation layer pattern 212 may be limited or even prevented during the removal of the gate mask 262.

In other embodiments according to the inventive concept, the gate mask 262 may be removed using a solution including hydrogen fluoride, deionized water, and one of a polar solvent and a strong acid containing sulfuric acid. The polar solvent may include, for example, alcohols, carboxylic acid, carbonyl, ether, ester or the like. In some embodiments according to the inventive concept, the solution may include about 80 to about 99.9% by weight of organic solvent, about 0.01 to about 10% by weight of hydrogen fluoride and about 0.1 to about 10% by weight of deionized water. The solution may have a high etching selectivity between an oxide doped with impurities and an oxide not including impurities, so that the gate insulation layer pattern 212 may not be damaged during the removal of the gate mask 262.

When the barrier layer pattern 252 has been formed, the barrier layer pattern 252 may also be removed.

As illustrated above, the gate mask 262 may be formed using a material having an etching selectivity with respect to the gate insulation layer 210, e. g., an oxide doped with impurities, and the gate electrode layer 220 and the gate insulation layer 210 may be patterned to form the gate electrode 222 and the gate insulation layer pattern 212, respectively. Thus, damage to the gate insulation layer pattern 212 during the removal of the gate mask 262 may be limited or even prevented, which may provide improved characteristics to a semiconductor structure including the gate electrode 222 and gate insulation pattern 212. Additionally, as the gate mask 262 may be removed, the gate structure may have a low aspect ratio so that a leaning phenomenon of the gate structure may be limited or even prevented.

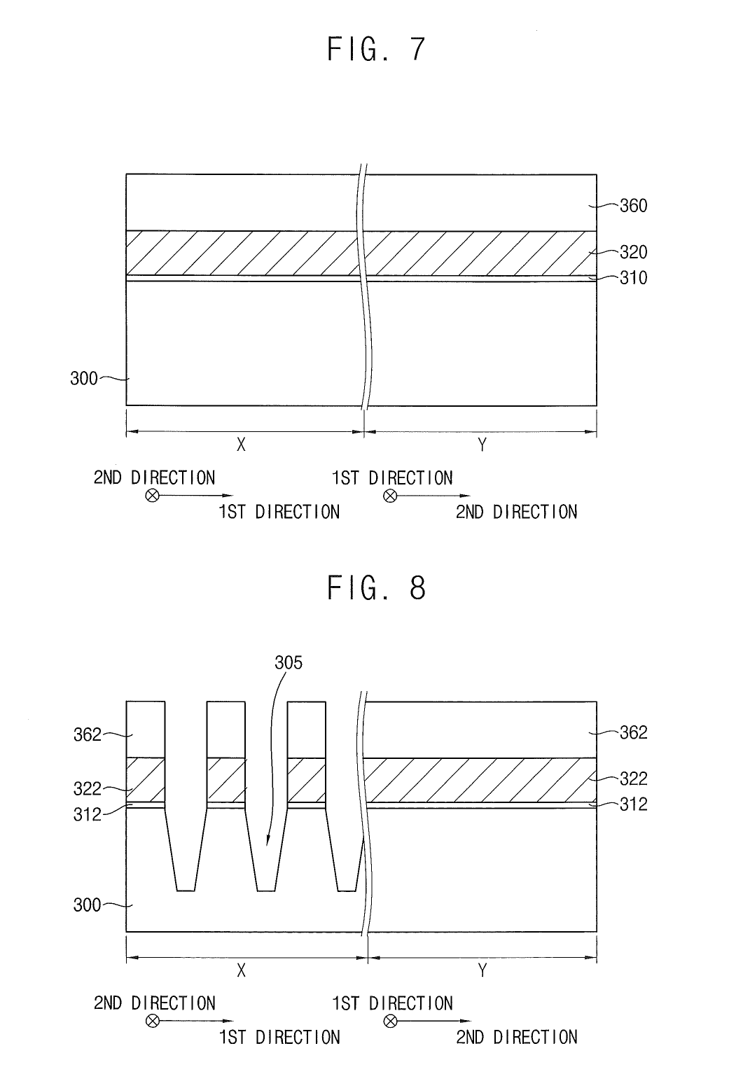

FIGS. 7 to 12 are cross-sectional views illustrating a method of forming a semiconductor device in accordance with some embodiments according to the inventive concept. In FIGS. 7 to 12, a first region X shows a cross-sectional view of the semiconductor device cut along a first direction, and a second region Y shows a cross-sectional view of the semiconductor device cut along a second direction perpendicular to the first direction. Referring to FIG. 7, an insulation layer 310, an electrode layer 320 and a first hard mask layer 360 may be sequentially formed on a substrate 300. A first barrier layer (not shown) may be further formed between the electrode layer 320 and the first hard mask layer 360.

The substrate 300 may be a semiconductor substrate, e. g., a silicon substrate, a germanium substrate, a silicon-germanium substrate, etc., a SOT substrate, a GUI substrate, or a single crystalline metal oxide substrate.

In some embodiments according to the inventive concept, the insulation layer 310 may be formed using an oxide that is substantially free of (or does not include) impurities. In some embodiments according to the inventive concept, the insulation layer 310 may be formed by performing a heat oxidation process or a radical oxidation process on a top surface of the substrate 300. In other embodiments according to the inventive concept, the insulation layer 310 may be formed by depositing an oxide on the substrate 300.

The electrode layer 320 may be formed using doped polysilicon, a metal, a metal silicide, a metal nitride or the like. The first hard mask layer 360 may be formed using a material having an etching selectivity with respect to the insulation layer 310. In some embodiments according to the inventive concept, the first hard mask layer 360 may be formed using an oxide doped with impurities. For example, the first hard mask layer 360 may be formed using BPSG. The first barrier layer may be formed using silicon nitride.

Referring now to FIG. 8, the first hard mask layer 360 may be patterned by a photolithography process to form a first hard mask 362. The electrode layer 320 and the insulation layer 320 may be patterned using the first hard mask 362 as an etching mask to form a floating gate layer 322 and a tunnel insulation layer 312, respectively. An upper portion of the substrate 300 may be also etched to form a trench 305. In some embodiments according to the inventive concept, an annealing process for curing damages to the substrate 300 during the formation of the trench 305 may be performed. When the first barrier layer is formed, the first barrier layer may be also patterned to form a barrier layer pattern (not shown).

In some embodiments according to the inventive concept, a plurality of floating gate layers 322 and a plurality of tunnel insulation layers 312 may be formed in the first direction, and each of the floating gate layers 322 and the tunnel insulation layers 312 may extend in the second direction.

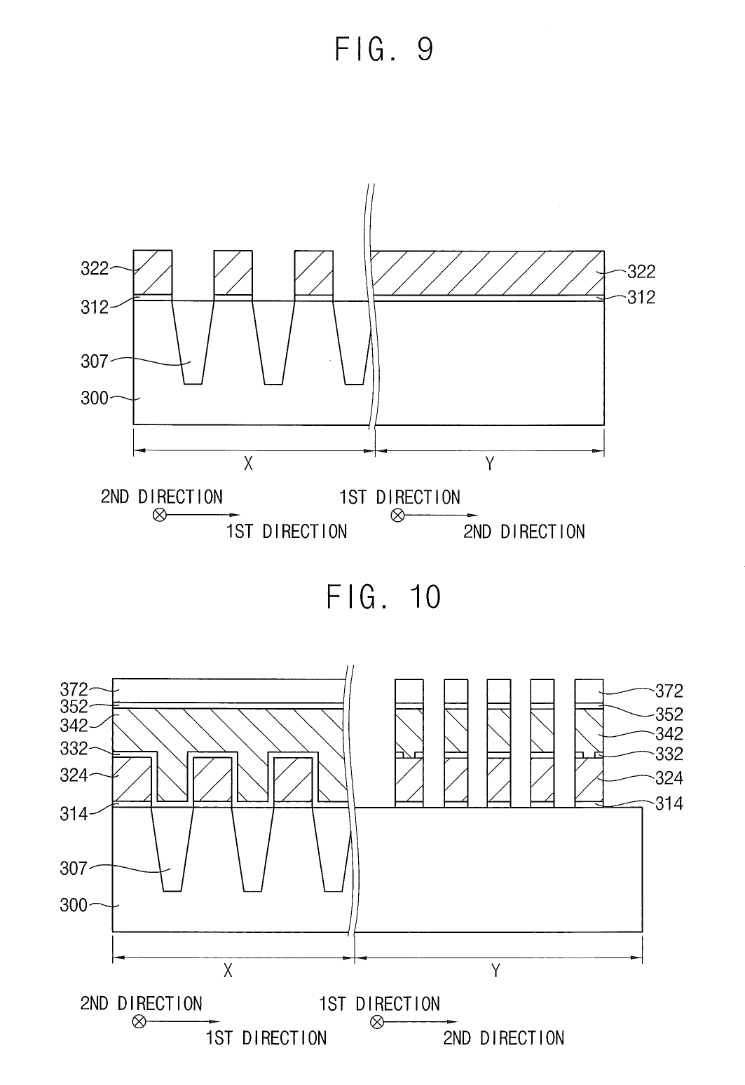

Referring to FIG. 9, the first hard mask 362 may be removed. In some embodiments according to the inventive concept, the first hard mask 362 may be removed using a gas including hydrogen fluoride (HF). The gas may further include deionized water vapor. The gas may have a high etching selectivity between an oxide doped with impurities and an oxide not including impurities, so that damage to the tunnel insulation layer 312 during the removal of the first hard mask 362 may be limited or even prevented.

In other embodiments according to the inventive concept, the first hard mask 362 may be removed using a solution including hydrogen fluoride, deionized water, and one of a polar solvent and a strong acid containing sulfuric acid. The polar solvent may include, for example, alcohols, carboxylic acid, carbonyl, ether, ester and the like. In some embodiments according to the inventive concept, the solution may include about 80 to about 99.9% by weight of organic solvent, about 0.01 to about 10% by weight of hydrogen fluoride and about 0.1 to about 10% by weight of deionized water. The solution may have a high etching selectivity between an oxide doped with impurities and an oxide not including impurities, so that damage to the tunnel insulation layer 312 during the removal of the first hard mask 362 may be limited or even prevented. When the first barrier layer pattern has been formed, the first barrier layer pattern may also be removed.

In some embodiments according to the inventive concept, an isolation layer may be formed on the substrate 300, the tunnel insulation layer 312 and the floating gate layer 322 to fill the trench 305. The isolation layer may be formed using tonen silazene (TOSZ), boro silicate glass (BSG), boro phosphor silicate glass (BPSG), undoped silicate glass (USG), spin on glass (SOG), flowable oxide (FOX), tetra ethyl ortho silicate (TEOS), high density plasma (HDP) oxide, high temperature oxide (HTO) or the like by a chemical vapor deposition (CVD) process, an atomic layer deposition (ALD) process or a physical vapor deposition (PVD) process. An upper portion of the isolation layer may be removed to form an isolation layer pattern 307 exposing sidewalls of the floating gate layer 322 and the tunnel insulation layer 312. In some embodiments according to the inventive concept, the isolation layer pattern 307 may be formed to have a height substantially the same as that of a top surface of the tunnel insulation layer 312.

In other embodiments according to the inventive concept, before removing the first hard mask 362, an isolation layer may be formed on the substrate 300, the tunnel insulation layer 312, the floating gate layer 322 and the first hard mask 362 to fill the trench 305. After planarizing the isolation layer until the floating gate layer 322 is exposed, an upper portion of the isolation layer may be removed to form the isolation layer pattern 307.

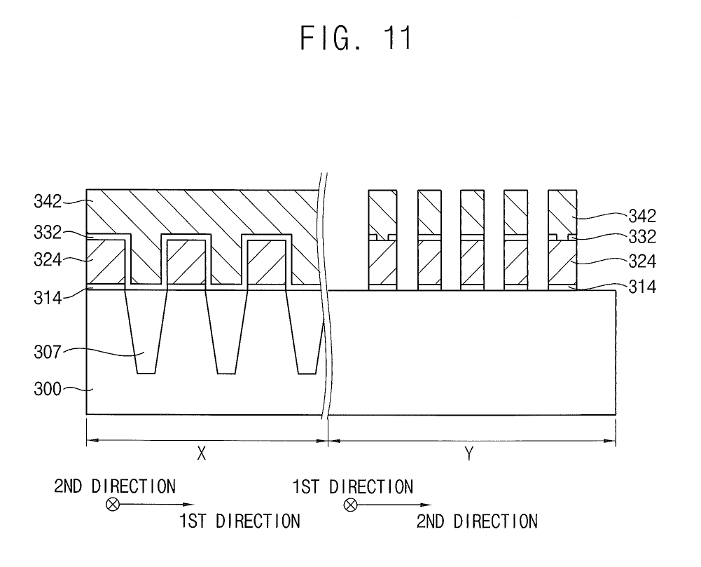

Referring now to FIG. 10, a dielectric layer, a control gate layer and a second hard mask layer may be sequentially formed on the tunnel insulation layer 312, the floating gate layer 322 and the isolation layer pattern 307. A portion of the dielectric layer may be removed so that the control gate layer may be electrically connected to the floating gate layer 322.

The dielectric layer may be formed using an oxide and/or a nitride. In some embodiments according to the inventive concept, the dielectric layer may be formed to have a multi-layered structure, e. g., an ONO structure including oxide layer/nitride layer/oxide layer. In other embodiments according to the inventive concept, the dielectric layer may be formed using a metal oxide having a high dielectric constant.

The control gate layer may be formed using doped polysilicon, a metal, a metal silicide, a metal nitride or the like. In some embodiments according to the inventive concept, the control gate layer may be formed to have a doped polysilicon layer, an ohmic layer, a diffusion barrier layer, an amorphous layer and a metal layer sequentially stacked on the dielectric layer. For example, the doped polysilicon layer may include p-type impurities, such as boron, indium or gallium, or n-type impurities such as phosphorus, arsenic or antimony. The ohmic layer may include titanium, tantalum, tungsten, molybdenum or an alloy thereof. The diffusion barrier layer may include tungsten nitride, titanium nitride, tantalum nitride, molybdenum nitride and the like. The amorphous layer may include a refractory metal silicide, such as amorphous tungsten silicide, amorphous titanium silicide, amorphous molybdenum silicide or amorphous tantalum silicide. The metal layer may include tungsten, titanium, tantalum, molybdenum or an alloy thereof.

The second hard mask layer may be formed using a material having an etching selectivity with respect to the tunnel insulation layer 312. In some embodiments according to the inventive concept, the second hard mask layer may be formed using an oxide doped with impurities, e. g., BPSG. The second hard mask layer may include a material substantially the same as that of the first hard mask layer 360.

A second barrier layer may be further formed between the control gate layer and the second hard mask layer. The second barrier layer may be formed using a material substantially the same as that of the first barrier layer.

The second hard mask layer may be patterned by a photolithography process to form a second hard mask 372. The control gate layer, the dielectric layer, the floating gate layer 322 and the tunnel insulation layer 312 may be patterned using the second hard mask 372 as an etching mask to form a control gate 342, a dielectric layer pattern 332, a floating gate 324 and a tunnel insulation layer pattern 314, respectively. When the second barrier layer is formed, the second barrier layer may also be patterned to form a second barrier layer pattern 352.

In some embodiments according to the inventive concept, a plurality of floating gates 324 and a plurality of tunnel insulation layer pattern 314 may be formed to have an island shape. A plurality of control gates 342 and a plurality of dielectric layer patterns 332 may be formed in the second direction, and each of the control gates 342 and the dielectric layer patterns 332 may extend in the first direction.

Referring now to FIG. 11, the second hard mask 372 may be removed to form the gate structure of a floating gate type memory device. Impurities may be implanted into an upper portion of the substrate 300 adjacent to the gate structure to form an impurity region (not shown).

The second hard mask 372 may be removed by a process substantially the same as that of the first hard mask 362. Accordingly, as the second hard mask 372 is removed, the gate structure may have a low aspect ratio, and thus a leaning phenomenon may be limited or even prevented.

When the second barrier layer pattern 352 has been formed, the second barrier layer pattern 352 may also be removed.

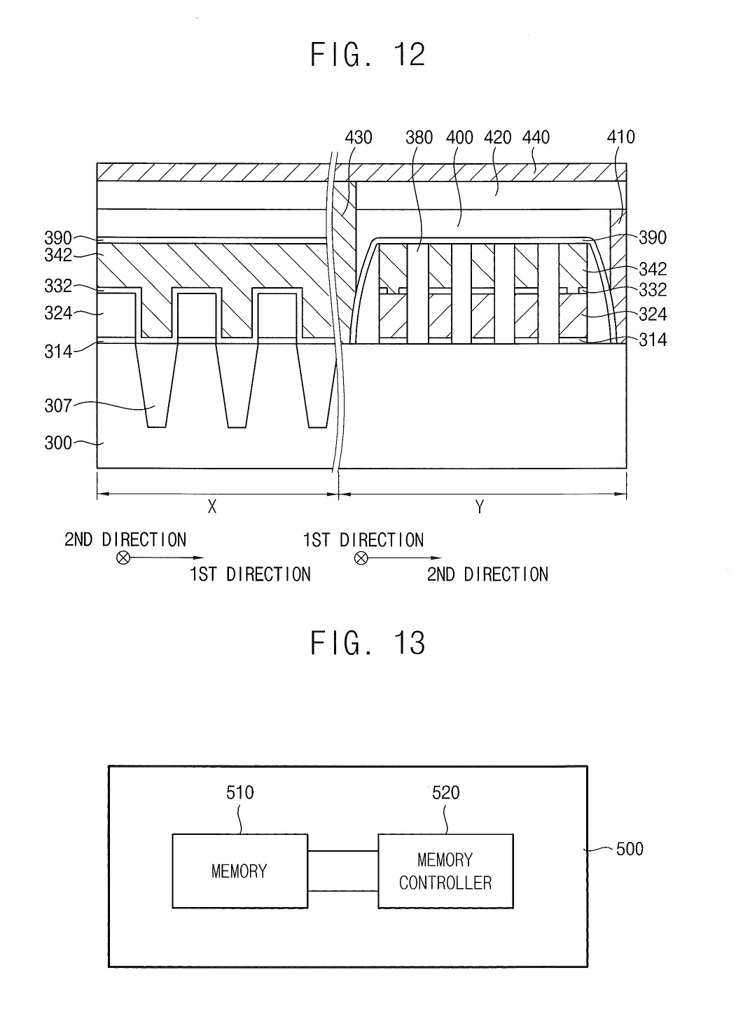

Referring to FIG. 12, a spacer layer covering the gate structure may be formed on the substrate 300 and anisotropically etched to form a spacer 380 between the gate structures and on sidewalls of the gate structures. In some embodiments according to the inventive concept, the spacer layer may be formed using silicon nitride.

In some embodiments according to the inventive concept, a capping layer 390 protecting the gate structure and the spacer 380 may be formed on the substrate 300. The capping layer 390 may be formed using silicon nitride.

A first insulating interlayer 400 may be formed on the substrate 300 to cover the gate structure and/or the capping layer 390. The first insulating interlayer 400 may be formed using an oxide, e. g., BPSG, USG SOG or the like.

A common source line (CSL) 410 may be formed through the first insulating interlayer 400 on the impurity region. The CSL 410 may be formed using doped polysilicon, a metal or a metal silicide.

A second insulating interlayer 420 may be foamed on the first insulating interlayer 400 and the CSL 410. The second insulating interlayer 420 may be formed using an oxide, e. g., BPSG, USG, SOG or the like.

A bit line contact 430 may be formed through the first and second insulating interlayers 400 and 420 on the impurity region. The bit line contact 430 may be formed using doped polysilicon, a metal or a metal silicide.

A bit line 440 may be formed on the second insulating interlayer 420 to be electrically connected to the bit line contact 430. In some embodiments according to the inventive concept, the bit line 440 may be formed to extend in the second direction. The bit line 440 may be formed using doped polysilicon, a metal or a metal silicide.

By the above illustrated processes, the semiconductor device may be manufactured. In FIGS. 7 to 12, a floating gate type memory device is illustrated, however, the inventive concept may also be applied to a charge trapping type memory device or the like.

FIG. 13 is a block diagram illustrating a system including the pattern or the gate structure formed by the method illustrated with reference to FIGS. 1 to 12 in accordance with example embodiments according to the inventive concept. Referring to FIG. 13, a system 500 may include a memory controller 520 connected to a memory 510. The memory 510 may be a DRAM or a flash memory (an NAND flash memory or an NOR flash memory) having the pattern or the gate structure formed by the method in accordance with embodiments according to the inventive concept such as describe above. The memory controller 520 may provide the memory 510 with input signals to control operations of the memory 510. For example, in the system 500, the memory controller 520 may transfer commands of a host to the memory 510 to control input/output data and/or may control various data of a memory based on an applied control signal. In some embodiments according to the inventive concept, the system 500 may be a memory card. In other embodiments according to the inventive concept, the inventive concept may be applied to other digital devices that include a similar operative association between a memory 510 and a memory controller 520.

Example embodiments according to the inventive concept provide a method of forming a pattern using a mask, wherein the pattern may not be damaged.

Example embodiments according to the inventive concept provide a method of forming a gate structure using a mask, wherein the gate structure may not be damaged.

Example embodiments according to the inventive concept provide a method of manufacturing a semiconductor device using the method of forming the gate structure.

According to example embodiments according to the inventive concept, there is provided a method of forming a pattern. In the method, an etching object layer having an oxide that does not include impurities is formed on a substrate. A mask including an oxide doped with impurities is formed on the etching object layer. The etching object layer is patterned using the mask as an etching mask. The mask is removed.

In example embodiments according to the inventive concept, the mask may include BPSG, and the etching object layer may include silicon oxide.

In example embodiments according to the inventive concept, the mask may be removed using a gas including hydrogen fluoride.

In example embodiments according to the inventive concept, the gas may further include deionized water vapor.

In example embodiments according to the inventive concept, the mask may be removed using a solution including hydrogen fluoride, deionized water, and one of a polar solvent and a strong acid containing sulfuric acid.

In example embodiments according to the inventive concept, removing the mask may be removed using a solution including about 80 to about 99.9% by weight of organic solvent, about 0.01 to about 10% by weight of hydrogen fluoride, and about 0.1 to about 10% by weight of deionized water.

In example embodiments according to the inventive concept, prior to forming the mask, a conductive layer may be further formed on the etching object layer, and when the etching object layer is patterned, the conductive layer may be also patterned.

In example embodiments according to the inventive concept, prior to forming the mask, a barrier layer may be further formed on the conductive layer, and when the etching object layer is patterned, the barrier layer may be also patterned.

According to example embodiments according to the inventive concept, there is provided a method of forming a gate structure. In the method, a gate insulation layer having an oxide that does not include impurities is formed on a substrate. A gate electrode layer is formed on the gate insulation layer. A gate mask including an oxide doped with impurities is formed on the gate electrode layer. The gate electrode layer and the gate insulation layer are patterned using the gate mask as an etching mask. The gate mask is removed.

In example embodiments according to the inventive concept, the gate mask may include BPSG.

In example embodiments according to the inventive concept, the gate mask may be removed using a gas including hydrogen fluoride.

In example embodiments according to the inventive concept, the gate mask may be removed using a solution including hydrogen fluoride, deionized water, and one of a polar solvent and a strong acid containing sulfuric acid.

In example embodiments according to the inventive concept, prior to forming the gate mask, a barrier layer may be further formed on the gate electrode layer, and when the gate electrode layer and the gate insulation layer are patterned, the barrier layer may be also patterned.

According to example embodiments according to the inventive concept, there is provided a method of manufacturing a semiconductor device. In the method, an insulation layer having an oxide that does not include impurities is formed on a substrate. A conductive layer is formed on the insulation layer. A first hard mask including an oxide doped with impurities is formed on the conductive layer. The conductive layer and the insulation layer are patterned using the first hard mask as an etching mask to form a floating gate layer and a tunnel insulation layer, respectively. A dielectric layer covering the floating gate layer is formed on the substrate, the dielectric layer. A control gate layer is formed on the dielectric layer. A second hard mask layer having an oxide doped with impurities is formed on the control gate layer. The control gate layer, the dielectric layer, the floating gate layer and the tunnel insulation layer are patterned using the second hard mask as an etching mask to form a control gate, a dielectric layer pattern, a floating gate and a tunnel insulation layer pattern, respectively. The second hard mask is removed.

In example embodiments according to the inventive concept, the first and second hard masks may include BPSG.

In example embodiments according to the inventive concept, the first and second hard masks may be removed using a gas including hydrogen fluoride.

In example embodiments according to the inventive concept, the first and second hard masks may be removed using a solution including hydrogen fluoride, deionized water, and one of a polar solvent and a strong acid containing sulfuric acid.

In example embodiments according to the inventive concept, prior to forming the second hard mask, a barrier layer may be further formed on the control gate layer using silicon nitride, and when the control gate layer, the dielectric layer, the floating gate layer and the tunnel insulation layer are patterned, the barrier layer may be also patterned.

In example embodiments according to the inventive concept, when the conductive layer and the insulation layer are patterned, a trench may be formed by removing an upper portion of the substrate.

In example embodiments according to the inventive concept, the control gate and the dielectric layer pattern may be patterned to extend in a given direction, and the floating gate and the tunnel insulation layer pattern may be patterned to have an island shape.

According to example embodiments according to the inventive concept, a gate mask may be formed on a gate electrode layer using a material having an etching selectivity with respect to a gate insulation layer under the gate electrode layer, e. g., an oxide doped with impurities, and the gate electrode layer and the gate insulation layer may be patterned using the gate mask as an etching mask to form a gate electrode and a gate insulation layer pattern, respectively. Thus, when the gate mask is removed, the gate insulation layer pattern may not be damaged. Additionally, because the gate mask is removed, the gate structure may have a low aspect ratio, and thus the leaning phenomenon may be prevented.

The foregoing is illustrative of example embodiments according to the inventive concept and is not to be construed as limiting thereof. Although a few example embodiments according to the inventive concept have been described, those skilled in the art will readily appreciate that many modifications are possible in the example embodiments according to the inventive concept without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments according to the inventive concept and is not to be construed as limited to the specific example embodiments according to the inventive concept disclosed, and that modifications to the disclosed example embodiments according to the inventive concept, as well as other example embodiments according to the inventive concept, are intended to be included within the scope of the appended claims.

What is claimed is:

1. A method of forming a pattern in a semiconductor device, the method comprising:
foaming an etching object layer on a substrate, the etching object layer comprising an oxide that is substantially free of impurities;
forming a mask on the etching object layer, the mask comprising an oxide that includes impurities;
patterning the etching object layer using the mask as an etching mask; and then
removing the mask using an etchant having an etching selectivity to an oxide that is substantially free of impurities and an oxide that includes impurities during removing of the mask to limit damage to the patterned etching object layer during removal of the mask.

2. The method of claim 1, wherein the etching object layer comprises an oxide that does not include any impurities and wherein the mask comprises an oxide that is doped with impurities.

3. The method of claim 1, wherein the mask includes boro phosphor silicate glass (BPSG) and the etching object layer includes silicon oxide.

4. The method of claim 3, wherein the etchant used in removing the mask is a gas that includes hydrogen fluoride and deionized water vapor.

5. The method of claim 3, wherein the etchant used in removing the mask is a solution including hydrogen fluoride, deionized water, and one of a polar solvent and a strong acid containing sulfuric acid.

6. The method of claim 3, wherein the etchant used in removing the mask is a solution including about 80 to about 99.9% by weight of organic solvent, about 0.01 to about 10% by weight of hydrogen fluoride, and about 0.1 to about 10% by weight of deionized water.

7. The method of claim 3, wherein the etchant used in removing the mask is a gas that includes hydrogen fluoride.

8. The method of claim 7, wherein the gas further includes deionized water vapor.

9. The method of claim 1, wherein the etchant used in removing the mask is a solution including hydrogen fluoride, deionized water, and one of a polar solvent and a strong acid containing sulfuric acid.

10. The method of claim 1, wherein the etchant used in removing the mask is a solution including about 80 to about 99.9% by weight of organic solvent, about 0.01 to about 10% by weight of hydrogen fluoride, and about 0.1 to about 10% by weight of deionized water.

11. The method of claim 1, wherein forming the mask is preceded by forming a barrier layer on the etching object layer of a material that limits movement of impurities from the mask into the etching object layer and wherein patterning the etching object layer further includes patterning the barrier layer.

12. The method of claim 11, wherein foaming the barrier layer comprises forming the barrier layer using silicon nitride to a thickness of about 50Å.

13. The method of claim 1, wherein the etching object layer comprises a gate insulation layer and wherein the mask comprises a gate mask and wherein in the method further comprises forming a gate electrode layer on the gate insulation layer and wherein forming a mask comprises forming the gate mask on the gate electrode layer and wherein patterning the etching object layer comprises patterning the gate electrode layer and the gate insulation layer using the gate mask as an etching mask.

14. The method of claim 13, wherein the gate mask includes boro phosphor silicate glass (BPSG) and wherein the gate mask comprises an oxide that is doped with impurities and wherein the etchant used in removing the gate mask includes hydrogen fluoride.

15. The method of claim 13, wherein forming the gate mask is preceded by forming a barrier layer on the gate electrode layer of a material that limits movement of impurities from the gate mask into the gate electrode layer and wherein patterning the gate electrode layer further includes patterning the barrier layer.

16. A method of forming a semiconductor device, comprising:
forming an insulation layer on a substrate, the insulation layer comprising an oxide that is substantially free of impurities;
forming a conductive layer on the insulation layer;
forming a first hard mask on the conductive layer, the first hard mask including an oxide doped with impurities;
patterning the conductive layer and the insulation layer using the first hard mask as an etching mask to form a floating gate layer and a tunnel insulation layer, respectively;
removing the first hard mask layer using an etchant having an etching selectivity to an oxide that is substantially free of impurities and an oxide that includes impurities during removing of the first hard mask to limit damage to the patterned conductive layer during removal of the first hard mask; and then
forming a dielectric layer on the substrate, the dielectric layer covering the floating gate layer;
forming a control gate layer on the dielectric layer;
fanning a second hard mask layer on the control gate layer, the second hard mask layer including an oxide doped with impurities;
patterning the control gate layer, the dielectric layer, the floating gate layer and the tunnel insulation layer using the second hard mask as an etching mask to form a control gate, a dielectric layer pattern, a floating gate and a tunnel insulation layer pattern, respectively; and
removing the second hard mask.

17. The method of claim 16, wherein the etchant used in removing the first hard mask and an etchant used in removing the second hard masks is a gas including hydrogen fluoride.

18. The method of claim 16, wherein removing the first and second hard masks is performed using a solution including hydrogen fluoride, deionized water, and one of a polar solvent and a strong acid containing sulfuric acid.

19. The method of claim 16, wherein patterning the conductive layer and the insulation layer further includes forming a trench by removing an upper portion of the substrate and wherein the control gate and the dielectric layer pattern are patterned to extend in a given direction, and the floating gate and the tunnel insulation layer pattern are patterned to have an island shape.
